(19) United States
(12) Patent Application Publication
(10) Pub. No.: US 2018/0144945 A1
(43) Pub. Date: May 24, 2018

(54) PLACING UNIT AND PLASMA PROCESSING APPARATUS

(71) Applicant: TOKYO ELECTRON LIMITED, Tokyo (JP)

(72) Inventors: Tomoyuki TAKAHASHI, Miyagi (JP); Daisuke HAYASHI, Miyagi (JP); Dai KITAGAWA, Miyagi (JP)

(73) Assignee: TOKYO ELECTRON LIMITED, Tokyo (JP)

(21) Appl. No.: 15/813,796

(22) Filed: Nov. 15, 2017

(30) Foreign Application Priority Data
Nov. 21, 2016 (JP) 2016-226024

(51) Int. Cl. H01L 21/3065; H01J 37/32; H01L 21/67; H01L 21/683

(52) U.S. Cl. CPC H01L 21/3065; H01J 37/32192; H01J 37/32091; H01J 37/32165; H01J 37/3244; H01J 37/32532; H01J 2237/334; H01J 37/32422; H01L 21/67063; H01L 21/6831; H01J 37/32678; H01J 2237/332; H01J 37/32816

(57) ABSTRACT

The present disclosure relates to a placing unit including: a base to which a high-frequency power is applied; an electrostatic chuck provided on the base and including a placing region configured to place a workpiece and an outer peripheral region configured to surround the placing region; a heater provided in the placing region; a wiring layer connected to the heater and extending to an inside of the outer peripheral region; a power supply terminal connected to a contact portion of the wiring layer in the outer peripheral region; and a conductive layer formed in the outer peripheral region or in other regions along a thickness direction of the outer peripheral region so as to overlap with the power supply terminal when viewed from thickness direction of the outer peripheral region.

### CROSS-REFERENCE TO RELATED APPLICATIONS

This application is based on and claims priority from Japanese Patent Application No. 2016-226024 filed on Nov. 21, 2016 with the Japan Patent Office, the disclosure of which is incorporated herein in its entirety by reference.

### TECHNICAL FIELD

Various aspects and exemplary embodiments of the present disclosure relate to a placing unit and a plasma processing apparatus.

### BACKGROUND

A plasma processing apparatus places a workpiece on a placing unit disposed in a processing container. The placing unit includes, for example, a base and an electrostatic chuck. The base is applied with a high-frequency power for plasma generation. The electrostatic chuck is formed of a dielectric and provided on the base, and has a placing region configured to place the processing target subject and an outer peripheral region configured to surround the placing region.

A heater used to control the temperature of the workpiece may be provided in the electrostatic chuck. For example, a structure has been known in which a heater is provided in the placing region of the electrostatic chuck and a wiring layer connected to the heater extends to the inside of the outer peripheral region so as to connect a contact portion of the wiring layer in the outer peripheral region with a power supply terminal for the heater. However, in the above-described structure, a portion of the high-frequency power applied to the base leaks from the power supply terminal for the heater to an external power source, and thus, high-frequency power is wasted.

In this regard, a technique has been known in which a filter is provided on a power supply line that connects a power supply terminal for a heater and an external power source so as to attenuate high-frequency power that is applied to a base and leaks from the power supply terminal for the heater to the power supply line. See, for example, Japanese Patent Laid-Open Publication Nos. 2013-175573, 2016-001688, and 2014-003179.

### SUMMARY

A placing unit of an aspect of the present disclosure includes: a base to which a high-frequency power is applied; an electrostatic chuck provided on the base and including a placing region configured to place a workpiece and an outer peripheral region configured to surround the placing region; a heater provided in the placing region; a wiring layer connected to the heater and extending to the inside of the outer peripheral region; a power supply terminal connected to a contact portion of the wiring layer in the outer peripheral region; and a conductive layer provided in the outer peripheral region or in other regions along the thickness direction of the outer peripheral region so as to overlap with the power supply terminal when viewed from the thickness direction of the outer peripheral region.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view schematically illustrating a plasma processing apparatus according to an exemplary embodiment.

FIG. 2 is a plan view illustrating a placing unit according to the exemplary embodiment.

FIG. 3 is a cross-sectional view taken along line I-I of FIG. 2.

FIG. 4 is a cross-sectional view illustrating a configuration example of a base, an electrostatic chuck, and a focus ring according to the exemplary embodiment.

FIG. 5 is a view for explaining an operation example of a conductive layer according to the exemplary embodiment.

FIG. 6 is a view for explaining another operation example of the conductive layer according to the exemplary embodiment.

FIG. 7 is a view illustrating a simulation result of an electric field strength depending on the presence/absence of the conductive layer.

FIG. 8 is a view illustrating an example of an installation state of the conductive layer according to the exemplary embodiment.

FIG. 9 is a view illustrating another example of the installation state of the conductive layer according to the exemplary embodiment.

FIG. 10 is a view illustrating yet another example of the installation state of the conductive layer according to the exemplary embodiment.

FIG. 11 is a view for explaining yet another operation example of the conductive layer according to the exemplary embodiment.

FIG. 12 is a view illustrating an effect by the plasma processing apparatus (a measurement result of an etching rate) according to the exemplary embodiment.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Since a filter is provided in correspondence to the number of heaters provided in an electrostatic chuck, when the number of the filters increases, a small filter with a low impulse value may be used as each filter from the viewpoint of avoiding the enlargement of a device. When such a small filter is applied to a placing unit, the high-frequency power leaking from a power supply terminal for a heater to a power supply line is not sufficiently attenuated and a potential locally decreases at a position corresponding to the power supply terminal for the heater in the circumferential position of a workpiece. As a result, the uniformity of an electric field strength along the circumferential direction of the workpiece may be impaired.

A placing unit according to a first aspect of the present disclosure includes: a base to which a high-frequency power is applied; an electrostatic chuck provided on the base and including a placing region configured to place a workpiece and an outer peripheral region configured to surround the placing region; a heater provided in the placing region; a wiring layer connected to the heater and extending to the inside of the outer peripheral region; a power supply terminal connected to a contact portion of the wiring layer in the outer peripheral region; and a conductive layer provided in the outer peripheral region or in other regions along the thickness direction of the outer peripheral region so as to overlap with the power supply terminal when viewed from the thickness direction of the outer peripheral region.

The above-described placing unit further includes a focus ring provided on the outer peripheral region, and the conductive region is provided in the focus ring along the thickness direction of the outer peripheral region or between the focus ring and the outer peripheral region so as to overlap with the power supply terminal when viewed from the thickness direction of the outer peripheral region.

In the above-described placing unit, the conductive layer is a conductive film that covers a surface facing the outer peripheral region of the focus ring.

In the above-described placing unit, the conductive layer is formed in a ring shape including a portion overlapping with the power supply terminal and a portion not overlapping with the power supply terminal when viewed from the thickness direction of the outer peripheral region.

In the above-described placing unit, the conductive layer is electrically insulated from other portions.

In the above-described placing unit, the conductive layer includes at least one of, for example, W, Ti, Al, Si, Ni, C, and Cu.

In the above-described placing unit, a plurality of the heaters are provided in the placing region, a plurality of the wiring layers are connected to the plurality of heaters, respectively, and extend to the inside of the outer peripheral region, the power supply terminal is provided for each of the wiring layers and is connected to a contact portion of the corresponding wiring layer in the outer peripheral region, and the conductive layer overlaps with a plurality of the power supply terminals when viewed from the thickness direction of the outer peripheral region.

The above-described placing unit further includes: a power supply line that connects the power supply terminal and an external power source; and a filter provided on the power supply line and configured to attenuate high-frequency power applied to the base and leaking from the power supply terminal to the power supply line.

In the above-described placing unit, a through hole through which a fixing member of the base penetrates is formed in the outer peripheral region, and the conductive layer is formed in other regions along the thickness direction of the outer peripheral region so as to overlap with the through hole in addition to the power supply terminal when viewed from the thickness direction of the outer peripheral region.

A placing unit according to a second aspect of the present disclosure includes: a base to which a high-frequency power is applied; an electrostatic chuck provided on the base and including a placing region configured to place a workpiece, an outer peripheral region configured to surround the placing region, and a through hole that penetrates the outer peripheral region; and a conductive layer formed in other regions along the thickness direction of the outer peripheral region so as to overlap with the through hole when viewed from the thickness direction of the outer peripheral region.

A plasma processing apparatus according to a third aspect of the present disclosure includes the above-described placing unit.

According to the above-described aspects, the placing unit of the present disclosure exhibits an effect of capable of improving the uniformity of the electric field strength along the circumferential direction of the workpiece.

Hereinafter, exemplary embodiments of the plasma processing apparatus disclosed herein will be described in detail with reference to the accompanying drawings. Meanwhile, in the respective drawings, the same or corresponding portions will be denoted by the same reference numerals.

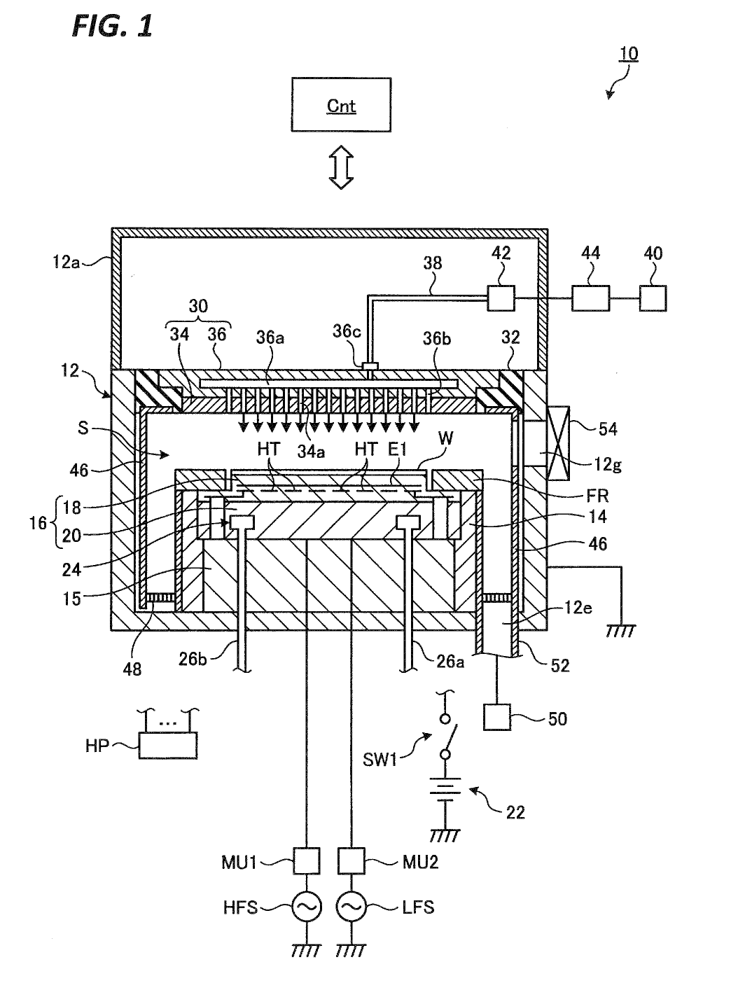

FIG. 1 is a view schematically illustrating a plasma processing apparatus 10 according to an exemplary embodiment. FIG. 1 schematically illustrates a structure in a longitudinal section of the plasma processing apparatus according to the exemplary embodiment. The plasma processing apparatus 10 illustrated in FIG. 1 is a capacitively coupled parallel plate plasma etching apparatus. The plasma processing apparatus 10 includes a substantially cylindrical processing container 12. The processing container 12 is made of, for example, aluminum, and the surface thereof is subjected to an anode oxidation processing.

A placing unit 16 is provided in the processing container 12. The placing unit 16 includes an electrostatic chuck 18, a focus ring FR, and a base 20. The base 20 has a substantially disc shape and its main portion is made of a conductive metal such as, for example, aluminum. The base 20 constitutes a lower electrode. The base 20 is supported by a support portion 14 and a support base 15. The support portion 14 is a cylindrical member that extends from the bottom portion of the processing container 12. The support base 15 is a cylindrical member that is disposed at the bottom portion of the processing container 12.

A first high-frequency power source HFS is electrically connected to the base 20 via a matching unit MU1. The first high-frequency power source HFS is a power source that generates high frequency power for generating plasma, and generates a high frequency power of 27 MHz to 100 MHz, for example, 40 MHz. The matching unit MU1 includes a circuit that matches an output impedance of the first high-frequency power source HFS with an input impedance of a load side (base 20 side).

Further, a second high-frequency power source LFS is electrically connected to the base 20 via a matching unit MU2. The second high-frequency power source LFS generates a high-frequency power (high-frequency bias power) for drawing ions into a wafer W to supply the high-frequency bias power to the base 20. The frequency of the high-frequency bias power is a frequency within a range of 400 kHz to 40 MHz, for example, 3 MHz. The matching unit MU2 includes a circuit that matches an output impedance of the second high-frequency power source LFS with an input impedance of the load side (base 20 side).

The electrostatic chuck 18 is provided on the base 20 and adsorbs the wafer W by an electrostatic force such as, for example, a coulomb force so as to hold the wafer W. The electrostatic chuck 18 has an electrostatic chucking electrode E1 in the main body made of dielectric material. A direct current power source 22 is electrically connected to the electrode E1 via a switch SW1. Further, a plurality of heaters HT are provided inside the electrostatic chuck 18. A heater power source HP is electrically connected to each heater HT. Each heater HT generates heat based on the power supplied individually from the heater power source HP to heat the electrostatic chuck 18. As a result, the temperature of the wafer W held by the electrostatic chuck 18 is controlled.

The focus ring FR is provided on the electrostatic chuck 18. The focus ring FR is provided to improve the uniformity of the plasma processing. The focus ring FR is made of dielectric and may be made of, for example, quartz.

A coolant flow path 24 is formed inside the base 20. The coolant flow path 24 is supplied with a coolant from a chiller unit provided outside the processing container 12 through a pipe 26a. The coolant supplied to the coolant flow path 24 is configured to be returned to the chiller unit through a pipe 26b. Further, the details of the placing unit 16 including the base 20 and the electrostatic chuck 18 will be described later.

An upper electrode 30 is provided in the processing container 12. The upper electrode 30 is disposed opposite to the base 20 above the placing unit 16, and the base 20 and the upper electrode 30 are provided substantially parallel to each other. A processing space S is defined between the base 20 and the upper electrode 30.

The upper electrode 30 is supported in the upper portion of the processing container 12 through an insulating shielding member 32. The upper electrode 30 may include an electrode plate 34 and an electrode support 36. The electrode plate 34 faces the processing space S and provides a plurality of gas ejection holes 34a. The electrode plate 34 may be made of a low-resistance conductor or semiconductor with little Joule heat.

The electrode support 36 detachably supports the electrode plate 34, and may be made of a conductive material such as, for example, aluminum. The electrode support 36 may have a water-cooled structure. A gas diffusion chamber 36a is provided in the electrode support 36. From the gas diffusion chamber 36a, a plurality of gas flowing holes 36b extend downward to be in communication with the gas ejection holes 34a. Further, a gas introduction port 36c is formed in the electrode support 36 to introduce the processing gas to the gas diffusion chamber 36a. The gas introduction port 36c is connected with a gas supply pipe 38.

The gas supply pipe 38 is connected with a gas source group 40 via a valve group 42 and a flow rate controller group 44. The valve group 42 includes a plurality of opening/closing valves, and the flow rate controller group 44 includes a plurality of flow rate controllers such as, for example, mass flow controllers. Further, the gas source group 40 includes a plurality of types of gas sources required for the plasma processing. The plurality of gas sources of the gas source group 40 are connected to the gas supply pipe 38 via the corresponding opening/closing valves and the corresponding mass flow controllers.

In the plasma processing apparatus 10, one or more gases from one or more gas sources selected from a plurality of gas sources of the gas source group 40 are supplied to the gas supply pipe 38. The gas supplied to the gas supply pipe 38 reaches the gas diffusion chamber 36a and is discharged to the processing space S through the gas flowing holes 36b and the gas discharge holes 34a.

Further, as illustrated in FIG. 1, the plasma processing apparatus 10 may further include a grounding conductor 12a. The grounding conductor 12a is a substantially cylindrical grounding conductor and is provided so as to extend above the height of the upper electrode 30 from the side wall of the processing container 12.

Further, in the plasma processing apparatus 10, a deposit shield 46 is detachably provided along the inner wall of the processing container 12. The deposit shield 46 is also provided in the outer periphery of the support portion 14. The deposit shield 46 serves to suppress an etching byproduct (deposit) from being attached to the processing container 12, and may be formed by coating a ceramic (e.g., Y₂O₃) on an aluminum material.

An exhaust plate 48 is provided between the support portion 14 and the inner wall of the processing container 12 at the bottom portion side of the processing container 12. The exhaust plate 48 may be formed by coating a ceramic (e.g., Y₂O₃) on an aluminum material. An exhaust port 12e is provided at the lower side of the exhaust plate 48 in the processing container 12. The exhaust port 12e is connected with an exhaust device 50 via an exhaust pipe 52. The exhaust device 50 includes a vacuum pump such as, for example, a turbo molecular pump, and is capable of decompressing the space in the processing container 12 to a desired degree of vacuum. A carry-in/out port 12g of the wafer W is provided in the sidewall of the processing container 12. The carry-in/out port 12g is able to be opened/closed by a gate valve 54.

Further, the plasma processing apparatus 10 may further include a controller Cnt. The controller Cnt is a computer including, for example, a processor, a storage unit, an input device, and a display device, and controls respective portions of the plasma processing apparatus 10. In the controller Cnt, an operator may execute an input operation of a command using the input device to manage the plasma processing apparatus 10, and may visualize and display the operation status of the plasma processing apparatus 10 by the display device. Further, the storage unit of the controller Cnt stores a control program for controlling various processings to be performed in the plasma processing apparatus 10 by the processor, or a program for performing a processing on respective portions of the plasma processing apparatus 10 in accordance with a processing condition, that is, a processing recipe.

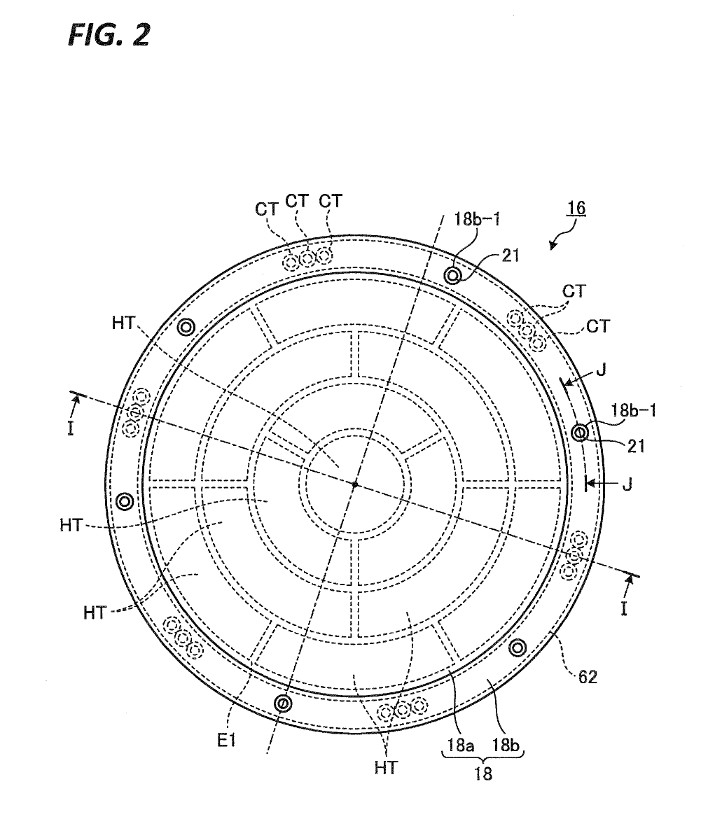

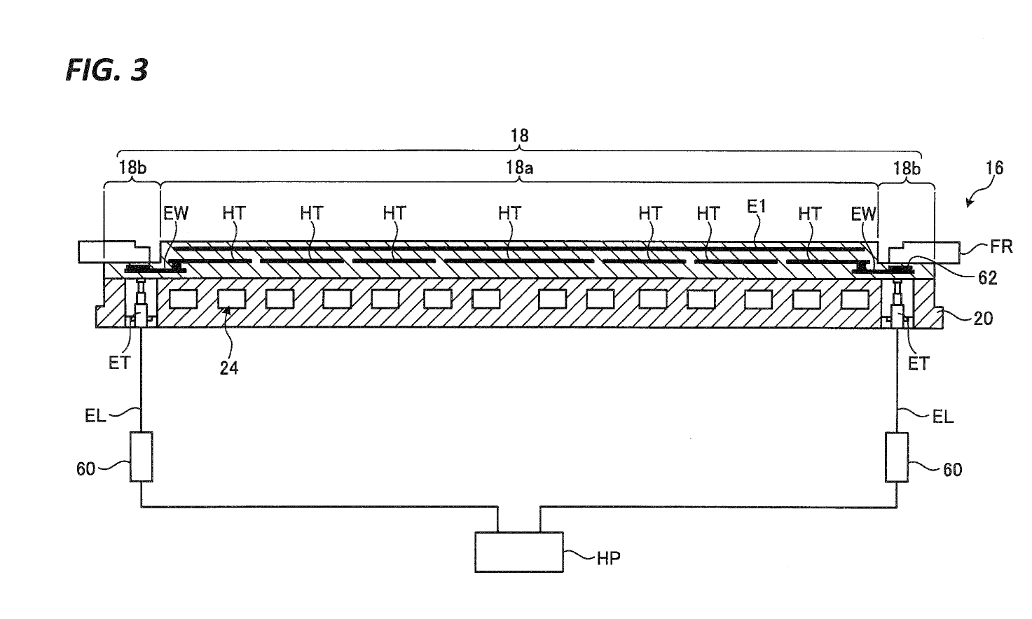

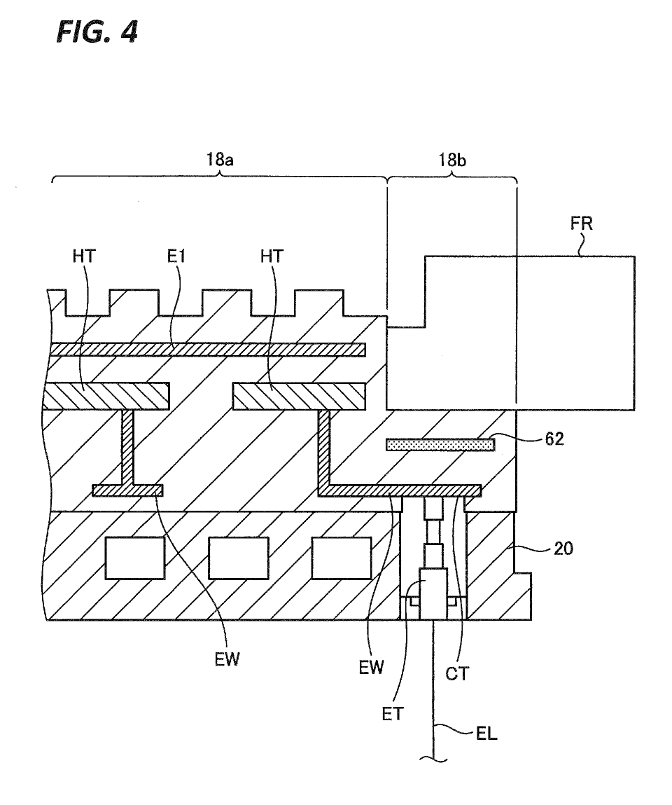

Next, the placing unit 16 will be described in detail. FIG. 2 is a plan view illustrating the placing 16 unit according to the exemplary embodiment. FIG. 3 is a cross-sectional view taken along line I-I of FIG. 2. FIG. 4 is a cross-sectional view illustrating a configuration example of a base 20, an electrostatic chuck 18, and a focus ring FR according to the exemplary embodiment. Further, FIG. 2 omits the focus ring FR for the sake of convenience of explanation.

As illustrated in illustrated in FIGS. 2 to 4, the placing unit 20 includes the electrostatic chuck 18, the focus ring FR, and the base 20. The electrostatic chuck 18 includes a placing region 18a and an outer peripheral region 18b. The placing region 18a is a substantially circular region in a plan view. The wafer, which is a workpiece, is placed on the placing region 18a. The upper surface of the placing region 18a is formed by, for example, top surfaces of a plurality of convex portions. In addition, the diameter of the placing region 18a is set to be substantially the same as that of the wafer W or slightly smaller than that of the wafer W. The outer peripheral region 18b is a region surrounding the placing region 18a and extends in a substantially annular shape. In the exemplary embodiment, the upper surface of the outer peripheral region 18b is located at a position lower than the upper surface of the placing region 18a. The focus ring FR is provided on the outer peripheral region 18b.

Further, a through hole 18b-1 penetrating the outer peripheral region 18b in the thickness direction is formed in the outer peripheral region 18b, and a fastening member 21 for fixing the base 20 to the support base 15 is inserted through the through hole 18b-1. In the exemplary embodiment, since the base 20 is fixed to the support base 15 by a plurality of fastening members 21, a plurality of through holes 18b-1 are formed in the outer peripheral region 18b in accordance with the number of the fastening members 21.

The electrostatic chuck 18 has an electrostatic chucking electrode E1 in the placing region 18a. As described above, the electrode E1 is connected to the direct current power source 22 via the switch SW1.

Further, a plurality of heaters HT are provided in the placing region 18a. For example, as illustrated in FIG. 2, the plurality of heaters HT are provided in a central circular region of the placing region 18a and in a plurality of concentric annular regions surrounding the circular region. Further, in each of the plurality of annular regions, the plurality of heaters HT are arranged in the circumferential direction. The plurality of heaters HT are supplied with individually regulated power from the heater power source HP. As a result, the heat generated by each heater HT is individually controlled, and the temperatures of the plurality of partial regions in the placing region 18a are individually adjusted.

As illustrated in FIGS. 3 and 4, a plurality of wiring layers EW are formed in the electrostatic chuck 18. The plurality of wiring layers EW are connected to the plurality of heaters HT, respectively, and extend to the inside of the outer peripheral region 18b. For example, each wiring layer EW may include a horizontally extending linear pattern and a contact via extending in a direction crossing with respect to the linear pattern (e.g., a vertical direction). In addition, each wiring layer EW constitutes a contact portion CT in the outer peripheral region 18b. The contact portion CT is exposed from the lower surface of the outer peripheral region 18b in the outer peripheral region 18b.

The contact portion CT is connected to a power supply terminal ET that supplies power generated by the heater power source HP. In the exemplary embodiment, as illustrated in FIG. 4, the power supply terminal ET is provided for each wiring layer EW, and penetrates the base 20 so as to be connected to the contact portion CT of the corresponding wiring layer EW in the outer peripheral region 18b. The power supply terminal ET and the heater power source HP are connected by a power supply line EL. A filter 60 is provided with the power supply line EL. The filter 60 attenuates the high-frequency power that is applied to the base 20 and leaks from the power supply terminal ET to the power supply line EL. The filter 60 is provided in correspondence to the number of the heaters HT. In the exemplary embodiment, since the plurality of heaters HT are provided, a plurality of filters 60 are provided in correspondence to the number of the heaters HT. Here, from the viewpoint of avoiding enlargement of the plasma processing apparatus 10, a small filter having a low impedance value may be used as each filter 60. When the small filter is applied to the placing unit 16, the high-frequency power that is applied to the base 20 and leaks from the power supply terminal ET to the power supply line EL is not sufficiently attenuated.

In addition, as illustrated in FIGS. 2 to 4, a conductive layer 62 formed of a conductive material is provided in the outer peripheral region 18b. The conductive region 62 overlaps with the power supply terminal ET when viewed from the thickness direction of the outer peripheral region 18b. Specifically, the conductive layer 62 is formed in a ring shape including a portion overlapping with the power supply terminal ET and a portion not overlapping with the power supply terminal ET when viewed from the thickness direction of the outer peripheral region 18b. Further, the conductive layer 62 is electrically insulated from other portions. As a result, in the conductive layer 62, a potential of the portion overlapping with the power supply terminal ET and the potential of the portion not overlapping with the power supply terminal ET become equal to each other. The conductive layer 62 includes at least one of, for example, W, Ti, Al, Si, Ni, C, and Cu.

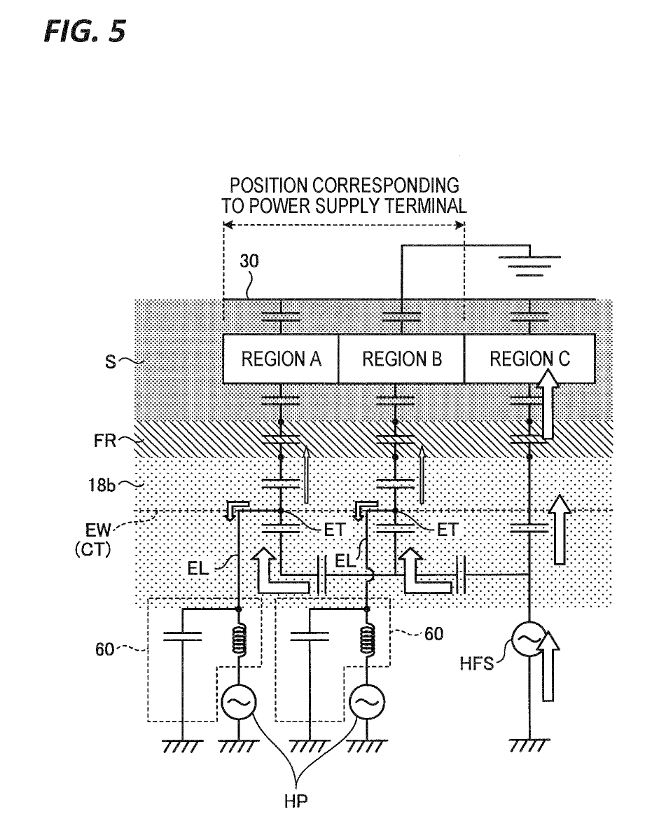

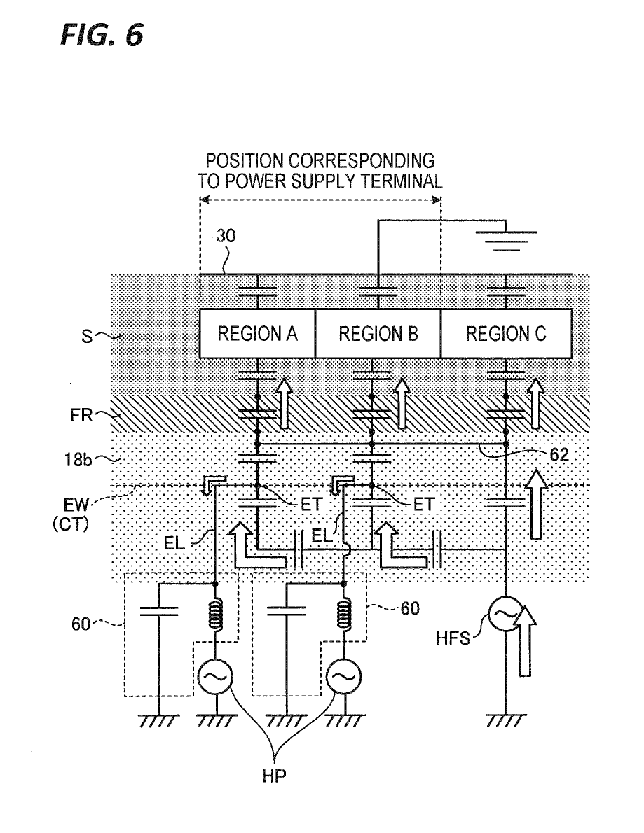

The operation of the conductive layer 62 will be described using an equivalent circuit of the plasma processing apparatus 10. FIGS. 5 and 6 are views for explaining an operation example of the conductive layer 62 according to the exemplary embodiment. The equivalent circuit illustrated in FIG. 5 corresponds to the plasma processing apparatus 10 in which the conductive layer 62 is not present. The equivalent circuit illustrated in FIG. 6 corresponds to the plasma processing apparatus 10 according to the exemplary embodiment, that is, the plasma processing apparatus 10 in which the conductive layer 62 is formed in the outer peripheral region 18b. In FIGS. 5 and 6, arrows indicate the flows of high-frequency powers, and the widths of the arrows indicate the magnitudes of the high-frequency powers.

As illustrated in FIGS. 5 and 6, a portion of the high-frequency power applied to the base 20 from the first high-frequency power source HFS leaks from the power supply terminal ET to the power supply line EL. The high-frequency power leaking from the power supply terminal ET to the power supply line EL is not sufficiently attenuated because the impedance value of the filter 60 is relatively small. Therefore, in a case where the conductive layer 62 is not present, as illustrated in FIG. 5, the potential locally falls at a position corresponding to the power supply terminal ET among the positions in the outer peripheral region 18b (i.e., positions in the circumferential direction of the wafer W), and the high-frequency power supplied to the processing space S locally falls. As a result, when the conductive layer 62 is not present, the uniformity of the electric field strength along the circumferential direction of the wafer W is impaired. In the example of FIG. 5, the electric field strengths of regions A and B corresponding to the power supply terminal ET decrease in comparison with the electric field strength of region C which does not correspond to the power supply terminal ET in the region of the processing space S along the circumferential direction of the wafer W.

When the conductive layer 62 is formed in the outer peripheral region 18b, the potential of the portion overlapping with the power supply terminal ET and the potential of the portion not overlapping with the power supply terminal ET become equal to each other in the conductive layer 62. Therefore, when the conductive layer 62 is formed in the outer peripheral region 18b, as illustrated in FIG. 6, a potential difference between the conductive layer 62 and the processing space S becomes constant along the circumferential direction of the wafer W, and the high-frequency power is uniformly supplied to the processing space S. As a result, when the conductive layer 62 is formed in the outer peripheral region 18b, the uniformity of the electric field strength along the circumferential direction of the wafer W may be improved. In the example of FIG. 6, a difference between the electric field strengths of the regions A and B corresponding to the power supply terminal ET and the electric field strength of the region C which does not correspond to the power supply terminal ET decreases in the region of the processing space S along the circumferential direction of the wafer W.

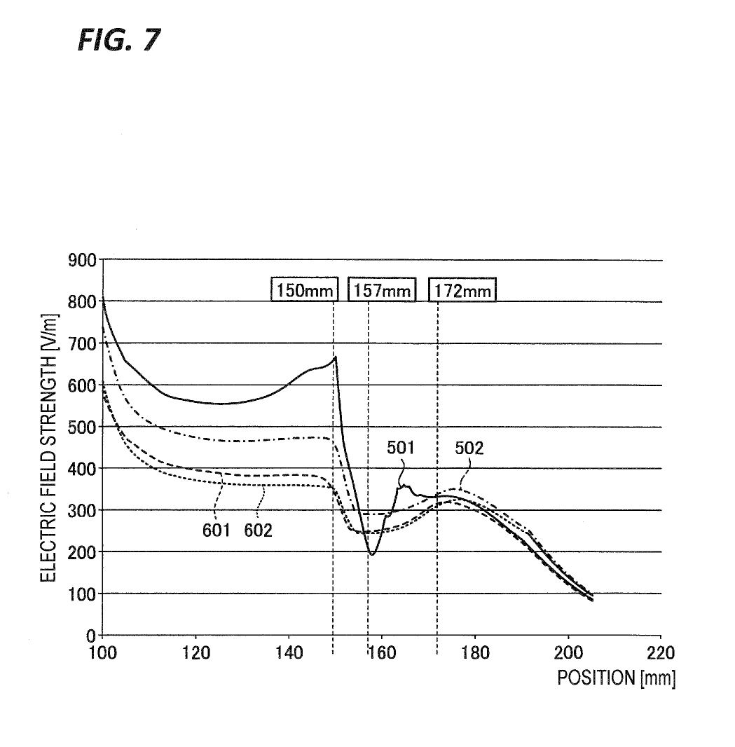

FIG. 7 is a view illustrating a simulation result of an electric field strength depending on the presence/absence of the conductive layer 62. In FIG. 7, the horizontal axis indicates the radial position [mm] of the wafer W with respect to the central position of the wafer W having a size of 300 mm, and the vertical axis indicates the electric field strength [V/m] of the processing space S. Further, the electric field strength of the processing space S is assumed to be the electric field strength at the position above the placing region 18a of the electrostatic chuck 18 by 3 mm. In addition, it is assumed that the position of 150 mm in the radial direction of the wafer W corresponds to the edge of the placing region 18a, the position of 157 mm in the radial direction of the wafer W corresponds to the power supply terminal ET, and the position of 172 mm in the radial direction of the wafer W corresponds to the edge of the outer peripheral region 18b.

Further, in FIG. 7, graph 501 represents the distribution of the electric field strength calculated in the region corresponding to the power supply terminal ET in the region of the processing space S along the circumferential direction of the wafer W when the conductive layer 62 is not present. Graph 502 represents the distribution of the electric field strength calculated in the region not corresponding to the power supply terminal ET in the region of the processing space S along the circumferential direction of the wafer W when the conductive layer 62 is not present.

In the meantime, in FIG. 7, graph 601 represents the distribution of the electric field strength calculated in the region corresponding to the power supply terminal ET in the region of the processing space S along the circumferential direction of the wafer W when the conductive layer 62 is provided in the outer peripheral region 18b. Graph 602 represents the distribution of the electric field strength calculated in the region not corresponding to the power supply terminal ET in the region of the processing space S along the circumferential direction of the wafer W when the conductive layer 62 is provided in the outer peripheral region 18b. In the simulation of FIG. 7, W was used as the conductive layer 62.

As illustrated in graphs 501 and 502 of FIG. 7, when the conductive layer 62 is not present, the electric field strength of the region corresponding to the power supply terminal ET was lowered when compared with the electric field strength of the region not corresponding to the power supply terminal ET.

As illustrated in graphs 601 and 602 of FIG. 7, when the conductive layer 62 is provided in the outer peripheral region 18b, a difference between the electric field strength of the region corresponding to the power supply terminal ET and the electric filed strength of the region not corresponding to the power supply terminal ET was lowered. That is, when the conductive layer 62 is formed in the outer peripheral region 18b, the uniformity of the electric field strength along the circumferential direction of the wafer W was able to be improved.

Next, a manner in which the conductive layer 62 according to the exemplary embodiment is installed will be described. In the exemplary embodiment, the conductive layer 62 is provided in the outer peripheral region 18b, but the conductive layer 62 may be provided in other regions along the thickness direction of the outer peripheral region 18b. That is, the conductive region 62 is formed in other regions along the thickness direction of the outer peripheral region 18b so as to overlap with the power supply terminal ET when viewed from the thickness direction of the outer peripheral region 18b.

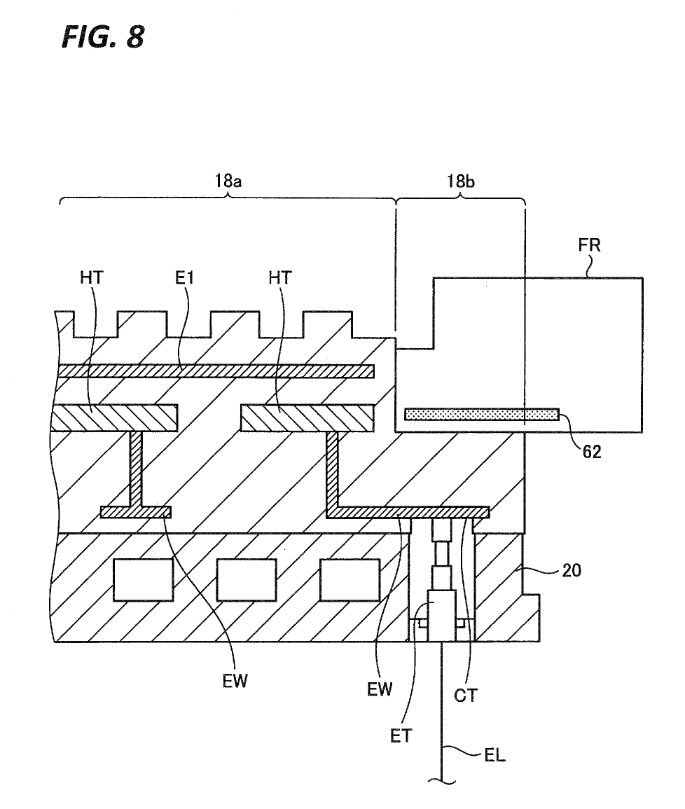

For example, as illustrated in FIG. 8, the conductive region 62 may be provided in the focus ring FR along the thickness direction of the outer peripheral region 18b so as to overlap with the power supply terminal ET when viewed from the thickness direction of the outer peripheral region 18b. FIG. 8 is a view illustrating an example of an installation state of the conductive layer 62 according to the exemplary embodiment. Like the conductive layer 62 illustrated in FIG. 2, the conductive layer 62 illustrated in FIG. 8 is formed in a ring shape including a portion overlapping with the power supply terminal ET and a portion not overlapping with the power supply terminal ET when viewed from the thickness direction of the outer peripheral region 18b. Further, the conductive layer 62 is electrically insulated from other portions. As a result, a potential of the portion overlapping with the power supply terminal ET and the potential of the portion not overlapping with the power supply terminal ET become equal to each other in the conductive layer 62.

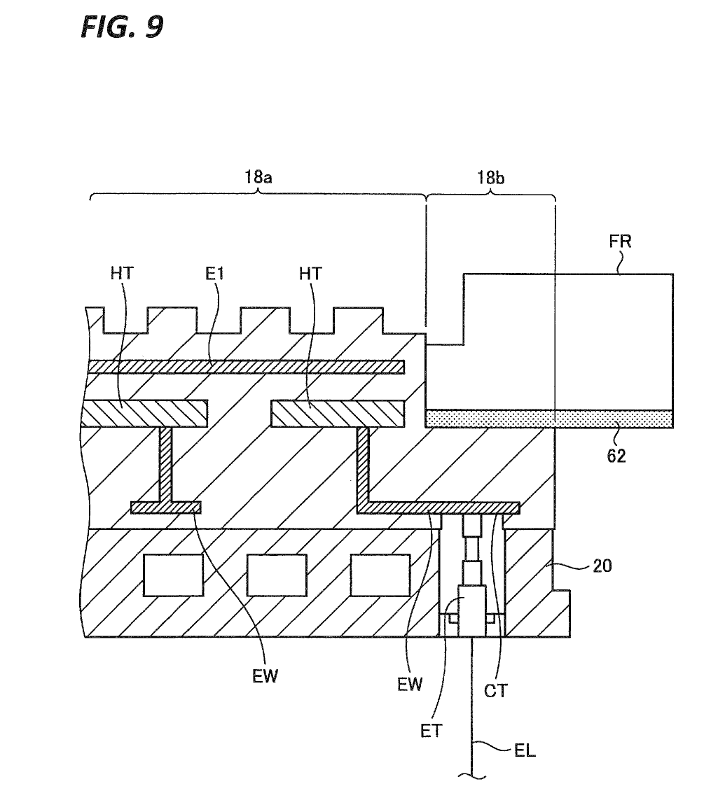

As another example, as illustrated in FIG. 9, the conductive layer 62 may be provided between the focus ring FR and the outer peripheral region 18b along the thickness direction of the outer peripheral region 18b so as to overlap with the power supply terminal ET when viewed from the thickness direction of the outer peripheral region 18b. FIG. 9 is a view illustrating another example of the installation state of the conductive layer 62 according to the exemplary embodiment. Like the conductive layer 62 illustrated in FIG. 2, the conductive layer 62 illustrated in FIG. 9 is formed in a ring shape including a portion overlapping with the power supply terminal ET and a portion not overlapping with the power supply terminal ET when viewed from the thickness direction of the outer peripheral region 18b. Further, the conductive layer 62 is electrically insulated from other portions. As a result, a potential of the portion overlapping with the power supply terminal ET and the potential of the portion not overlapping with the power supply terminal ET become equal to each other in the conductive layer 62. Further, the description of FIG. 9 represents a case where the conductive layer 62 and the focus ring FR are separate members, but the conductive layer 62 may be a conductive film that covers a surface facing the outer peripheral region 18b of the focus ring FR.

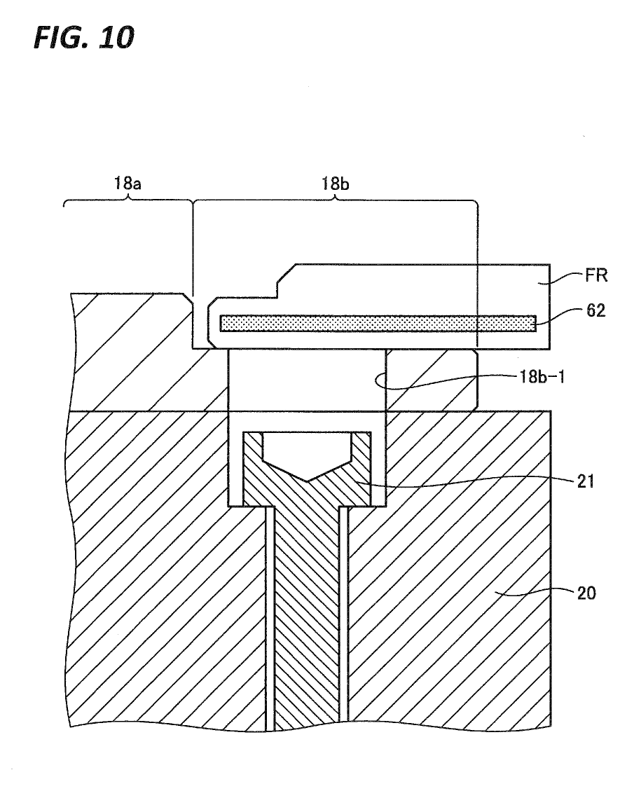

In addition, the conductive region 62 may be provided in other regions along the thickness direction of the outer peripheral region 18b so as to overlap with the through hole 18b-1 of the outer peripheral region 18b in addition to the power supply terminal ET when viewed from the thickness direction of the outer peripheral region 18b. For example, as illustrated in FIG. 10, the conductive layer 62 may be provided in the focus ring FR along the thickness direction of the outer peripheral region 18b so as to overlap with the through hole 18b-1 of the outer peripheral region 18b in addition to the power supply terminal ET when viewed from the thickness direction of the outer peripheral region 18b. FIG. 10 is a view illustrating a third example of the installation state of the conductive layer 62 according to the exemplary embodiment. FIG. 10 is a cross-sectional view taken along line J-J of FIG. 2. The conductive layer 62 illustrated in FIG. 10 is formed in a ring shape including a portion overlapping with the power supply terminal ET, a portion not overlapping with the power supply terminal ET, a portion overlapping with the through hole 18b-1, and a portion not overlapping with the through hole 18b-1 when viewed from the thickness direction of the outer peripheral region 18b. Further, the conductive layer 62 is electrically insulated from other portions. As a result, the potential of the portion overlapping with the power supply terminal ET, the potential of the portion not overlapping with the power supply terminal ET, the potential of the portion overlapping with the through hole 18b-1, and the potential of the portion not overlapping with the through hole 18b-1 become equal to each other in the conductive layer 62.

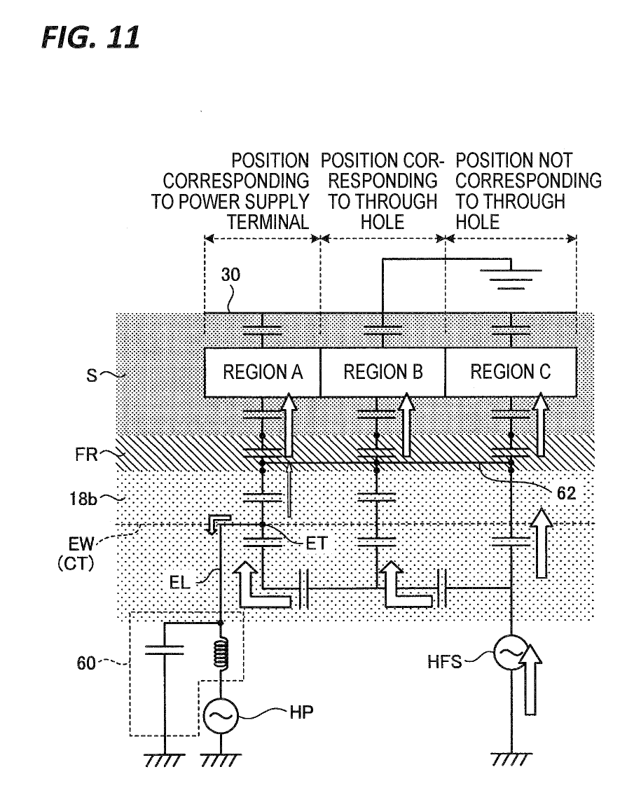

Here, the operation of the conductive layer 62 illustrated in FIG. 10 will be described using an equivalent circuit of the plasma processing apparatus 10. FIG. 11 is a view for explaining another operation example of the conductive layer 62 according to the exemplary embodiment. The equivalent circuit illustrated in FIG. 11 corresponds to the plasma processing apparatus 10 according to the exemplary embodiment, that is, the plasma processing apparatus 10 in which the conductive layer 62 is formed in the focus ring FR. In FIG. 11, arrows indicate the flows of high-frequency powers, and the widths of the arrows indicate the magnitudes of the high-frequency power.

As described above, when the conductive layer 62 is provided in the focus ring FR, the potential of the portion overlapping with the power supply terminal ET, the potential of the portion not overlapping with the power supply terminal ET, the potential of the portion overlapping with the through hole 18b-1, and the potential of the portion not overlapping with the through hole 18b-1 become equal to each other. Therefore, when the conductive layer 62 is provided in the focus ring FR, as illustrated in FIG. 11, a potential difference between the conductive layer 62 and the processing space S becomes constant along the circumferential direction of the wafer W, and the high-frequency power is uniformly supplied to the processing space S. As a result, when the conductive layer 62 is provided in the focus ring FR, the uniformity of the electric field strength along the circumferential direction of the wafer W may be improved. In the example of FIG. 11, the electric field strength of the region A corresponding to the power supply terminal ET, the electric field strength of the region B corresponding to the through hole 18b-1, and the electric field strength of the region C not corresponding to the through hole 18b-1 become substantially equal to each other in the region of the processing space S along the circumferential direction of the wafer W.

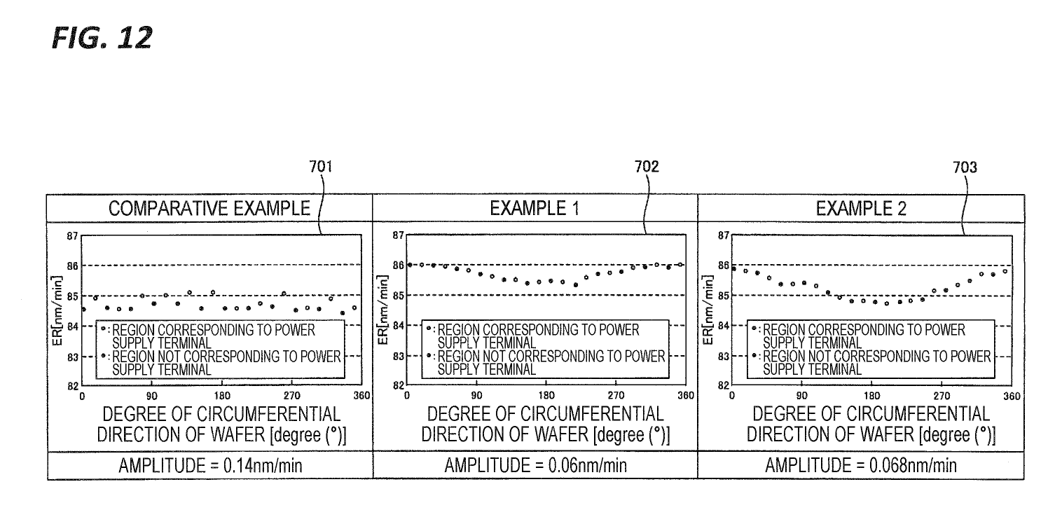

Next, an effect by the plasma processing apparatus 10 (a measurement result of an etching rate) according to the exemplary embodiment will be described. FIG. 12 is a view illustrating an effect by the plasma processing apparatus 10 (a measurement result of an etching rate) according to the exemplary embodiment. FIG. 12 includes graphs 701 to 703.

Graph 701 represents the measurement result obtained by measuring the distribution of the etching rate along the circumferential direction of the wafer W having a size of 300 mm using the plasma processing apparatus 10 in which the conductive layer 62 is not present (Comparative Example). Graph 702 represents the measurement result obtained by measuring the distribution of the etching rate along the circumferential direction of the wafer W having a size of 300 mm using the plasma processing apparatus 10 in which the conductive layer 62 is provided in the outer peripheral region 18b (Example 1). Graph 703 represents the measurement result obtained by measuring the distribution of the etching rate along the circumferential direction of the wafer W having a size of 300 mm using the plasma processing apparatus 10 in which the conductive layer 62 is provided in the focus ring FR (Example 2). In graphs 701 to 703, the horizontal axis indicates the circumferential angle [degree (°)] of the wafer W with respect to a predetermined position of the edge portion of the wafer W, and the vertical axis indicates the etching rate [nm/min] at a position of 3 mm from the end portion of the wafer W along the radial direction of the wafer W. Further, in each graph, the etching rate in the region corresponding to the power supply terminal ET is indicated by a white circle, and the etching rate in the region not corresponding to the power supply terminal ET is indicated by a black circle.

As illustrated in FIG. 12, in the Comparative Example, an “amplitude,” which is a difference between the average value of the etching rate in the region corresponding to the power supply terminal ET and the average value of the etching rate in the region not corresponding to the power supply terminal ET in a predetermined range along the circumferential direction of the wafer W, was 0.14 nm/min.

In Example 1, the above-mentioned “amplitude” was 0.060 nm/min, and in Example 2, the above-mentioned “amplitude” was 0.068 nm/min. That is, in Examples 1 and 2, the variation in the etching rate along the circumferential direction of the wafer W was suppressed when compared with the Comparative Example. This is probably because when the conductive layer 62 was provided in the outer peripheral region 18b or the focus ring FR, the uniformity of the electric field strength along the circumferential direction of the wafer W was improved, whereby the unevenness of the etching rate along the circumferential direction of the wafer W was improved locally.

According to the exemplary embodiment described above, the conductive layer 62 superimposed on the power supply terminal ET when viewed from the thickness direction of the outer peripheral region 18b is formed in the outer peripheral region 18b of the electrostatic chuck 18 or in other regions along the thickness direction of the outer peripheral region 18b. Therefore, according to the exemplary embodiment, a local decrease in the potential at the position corresponding to the power supply terminal ET in the circumferential position of the wafer W may be avoided, and the uniformity of the electric field strength along the circumferential direction of the wafer W may be improved. As a result, the unevenness of the etching rate along the circumferential direction of the wafer W may be improved.

In addition, in the exemplary embodiment, a case where the conductive layer 62 overlaps with the power supply terminal ET when viewed from the thickness direction of the outer peripheral region 18b has been described. However, the conductive layer 62 may be provided to overlap with a portion of the wiring layer EW in addition to the power supply terminal ET when viewed from the thickness direction of the outer peripheral region 18b. In this case, the ratio of the overlapping portion between the wiring layer EW and the conductive layer 62 to the portion corresponding to the outer peripheral region 18b of the wiring layer EW may be 76% or more.

Further, in the exemplary embodiment, the first high-frequency power source HFS, which is a power supply that generates high-frequency power for generating plasma, is electrically connected to the base 20 via the matching unit MU1, but the first high-frequency power source HFS may be connected to the upper electrode 30 via the matching unit MU1.

The plasma processing apparatus 10 in the exemplary embodiment is a capacitively coupled parallel plate plasma (CCP) etching apparatus. Examples of the plasma source may include an inductively coupled plasma (ICP), a microwave plasma, a surface wave plasma (SWP), a radial line slot antenna (RLSA) plasma, and an electron cyclotron resonance (ECT) plasma.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A placing unit comprising:
a base to which a high-frequency power is applied;
an electrostatic chuck provided on the base and including a placing region configured to place a workpiece and an outer peripheral region configured to surround the placing region;
a heater provided in the placing region;
a wiring layer connected to the heater and extending to an inside of the outer peripheral region;
a power supply terminal connected to a contact portion of the wiring layer in the outer peripheral region; and
a conductive layer formed in the outer peripheral region or in other regions along a thickness direction of the outer peripheral region so as to overlap with the power supply terminal when viewed from the thickness direction of the outer peripheral region.

2. The placing unit of claim 1, further comprising: a focus ring provided on the outer peripheral region,
wherein the conductive layer is formed in the focus ring along the thickness direction of the outer peripheral region or between the focus ring and the outer peripheral region so as to overlap with the power supply terminal when viewed from the thickness direction of the outer peripheral region.

3. The placing unit of claim 2, wherein the conductive layer is a conductive film that covers a surface facing the peripheral region of the focus ring.

4. The placing unit of claim 1, wherein the conductive layer is formed in a ring shape including a portion overlapping with the power supply terminal and a portion not overlapping with the power supply terminal when viewed from the thickness direction of the outer peripheral region.

5. The placing unit of claim 1, wherein the conductive layer is electrically insulated from other portions.

6. The placing unit of claim 1, wherein the conductive layer includes at least one of W, Ti, Al, Si, Ni, C, and Cu.

7. The placing unit of claim 1,
wherein a plurality of the heaters are provided in the placing region,
a plurality of the wiring layers are connected to the plurality of the heaters, respectively, and extend to the inside of the outer peripheral region,
the power supply terminal is provided for each of the wiring layers and is connected to a contact portion of a corresponding wiring layer in the outer peripheral region, and
the conductive layer overlaps with a plurality of the power supply terminals when viewed from the thickness direction of the outer peripheral region.

8. The placing unit of claim 1, further comprising:
a power supply line that connects the power supply terminal and an external power source; and
a filter provided on the power supply line and configured to attenuate a high-frequency power that is applied to the base and leaks from the power supply terminal to the power supply line.

9. The placing unit of claim 1, wherein a through hole through which a fixing member of the base penetrates is formed in the outer peripheral region, and
the conductive layer is formed in other regions along the thickness direction of the outer peripheral region so as to overlap with the through hole in addition to the power supply terminal when viewed from the thickness direction of the outer peripheral region.

10. A placing unit comprising:
a base to which a high-frequency power is applied;
an electrostatic chuck provided on the base and including a placing region configured to place a workpiece, an outer peripheral region configured to surround the placing region, and a through hole that penetrates the outer peripheral region; and
a conductive layer formed in other regions along a thickness direction of the outer peripheral region so as to overlap with the through hole when viewed from the thickness direction of the outer peripheral region.

11. A plasma processing apparatus comprising the placing unit of claim 1.
